(19) United States
(12) Patent Application Publication
(10) Pub. No.: US 2006/0263630 A1
(43) Pub. Date: Nov. 23, 2006

(54) Iridium complex and electroluminescent device using the same

(75) Inventors: Chan-Yuan Ho, Longtan Township (TW); Sung-Cheng Hu, Longtan Township (TW); Tsair-Feng Lin, Longtan Township (TW); Chih-An Wang, Longtan Township (TW); Yun-Chin Ho, Longtan Township (TW); Chuan-Yu Chou, Longtan Township (TW)

Correspondence Address: HDSL, 4331 STEVENS BATTLE LANE, FAIRFAX, VA, 22033, US

(73) Assignee: CHUNG SHAN INSTITUTE OF SCIENCE AND TECHNC

(21) Appl. No.: 11/134,400

(22) Filed: May 23, 2005

(51) Int. Cl. H01L 51/54; H05B 33/14; C09K 11/06

(52) U.S. Cl. 428/690; 428/917; 546/4; 252/301.16; 313/504; 313/506; 257/E51.044

(57) ABSTRACT

An iridium complex is used as a phosphorescent material in an organic electroluminescence (OEL). Use this complex as the red light guest dopant emitter of the phosphorescent material, then apply the phosphorescent material to the OEL light-emitting layer, a red light that is very close to pure red can be achieved. In addition, the iridium complex can increase the thermal stability of the OEL, due to their high conjugated structure.

### BACKGROUND

1. Field of Invention

This invention relates to an iridium complex, and its applications in phosphorescent material and organic electroluminescence (OEL).

2. Related Art

The organic electroluminescence (OEL) provides a new technology beyond what other flat-panel display technologies have achieved—a brighter and clearer full color displays with a faster response time. OEL is the most promising technology to replace the current LCD display because it possesses special properties such as self-emission, a wide viewing angle, quick response time, motion video image displaying capability, high electroluminescence quantum efficiencies, low energy consumption, etc. and can function without any backlights or color filters.

The basic requirement for a successful marketing of OEL display is the display of full color. Therefore, developing red, blue, and green color lights to fulfill commercial needs is the key step for its commercialization. So far, the green color lift has been well developed. As for the red color-emitting OEL, the stability of the material efficiency, and the purity of the emitted light are still not optimized. Among developed methods so far, the most common one, as described in U.S. Pat. No. 4,769,292, was to mix a small amount of red luminescent compounds as guest emissive dopants in a host layer of green luminescent compounds in order to adjust the spectrum and the efficiency of the light-emitting material. Based on this, a more advanced technology was developed by including phosphorescent organic heavy metal complexes in host luminescent compounds to surpass the 25% internal self-emission limitation in luminescent material. As depicted in a NATURE article in 1998 “Highly efficient phosphorescent emission from organic electroluminescent devices”; by mixing platinum octaethlyporphyrin (PtOEP) (the guest emitting dopant) with the host luminescent material 3-(8-hydroxyquinolate) aluminum (Alq3), the efficiency of internal energy transfer was highly increased, owing to the concurrent involvement of the singlet- and the triplet-state energy transfer in the luminescent material.

The development of a new phosphorescent material, as a guest dopant, and their application in the light emitting layer of OEL is the most important topic in the research of organic light-emitting materials. It is reported in a patent application (PCT/US00/32511) submitted by the Universal Display Corporation (UDC) USA, through the PATENT COOPERATION TREATY, that a new phosphorescent material—iridium(III) bis(2-(2′-bezenothienyl)-pyridinato-N,C^{3′}) (acetylacetonate) Ir(btp)₂acac), when applied in OEL, can emit a near pure red light of 617 nm wavelength with a 351.8° C. melting temperature. Accordingly, further research and development of a phosphorescent material with a better thermal stability, emission efficiency, and color purity will be very useful to OEL technology in terms of increasing its thermal stability in a high temperature environment and extending its lifetime. This will also help the development and application of OEL in full color display.

### SUMMARY

This invention provides an iridium complex. One of its applications is as the red light guest emitting dopants in OEL.

The iridium complex iridium(III) bis(2-(9′-phenathyl)-pyridinato-N,C^{10′}) (acetylacetonate) (Ir(pyp)₂acac) in this invention has the structure as shown in the following formula (I): 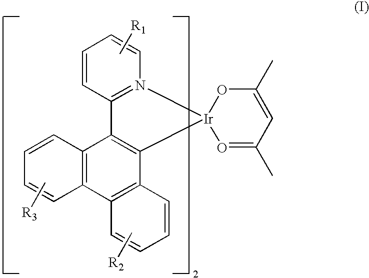
where R1, R2, and R3 are hydrogen atoms, an alkyl group with 1 to 3 carbons or an aryl group with 6 to 10 carbons. The iridium complex in this invention has a high conjugated structure and superior thermal stability.

This invention also provides a phosphorescent material that has a host compound and a guest dopant. The guest dopant of the material is an iridium complex with the chemical formula described in (I), where R1, R2, and R3 are hydrogen atoms, an alkyl group with 1 to 3 carbons or an aryl group with 6 to 10 carbons.

Another goal of this invention is to provide an OEL that contains an indium complex. The OEL includes a pair of electrodes and layers of organic light-emitting materials. The electrodes are on the two sides of the organic material layers to provide power sources for light emission. The organic light-emitting layers are made of phosphorescent material that contains a host compound and a guest dopant. The guest dopant is an iridium complex that has the chemical structure described in formula (I).

The two electrodes are an anode and a cathode. When a direct current is connected to OEL, electrons are injected from the cathode, while holes are injected from the anode.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become parent to those skilled in the art from this detailed description.

### BRIEF DESCRIPTION OF THE DRAWINGS

The present invention will become more fully understood from the detailed description given hereinbelow illustration only, and thus does not limit the invention, and wherein:

FIG. 1 shows the structure of the OEL in his invention; and

FIG. 2 shows the wave length emitted by the OEL in this invention

### DETAILED DESCRIPTION

This invention introduces an iridium complex, a phosphorescent material and an OBL that contains iridium complexes; the use of iridium complexes as the red light guest dopant of phosphorescent material and its application in OEL.

The iridium complex in this invention can be combined with various ionic groups. The structure of the iridium complex was described in chemical formula (I), where R1, R2, and R3 are hydrogen atoms, an alkyl group with 1 to 3 carbons or an aryl group with 6 to 10 carbons.

For example, the following chemical compounds (A) through (E) will fulfill the requirement of this invention's iridium complex:

(A) R1, R2, and R3 are hydrogen atoms.

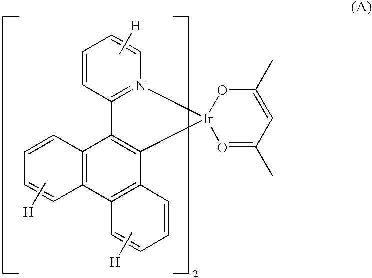

(B) R1, R2, and R3 are methyl groups (—CH₃).

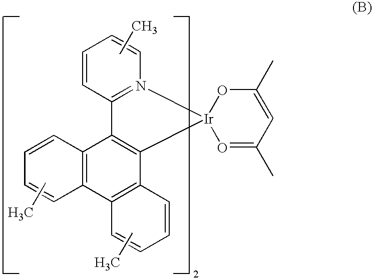

(C) R1, R2, and R3 are ethyl groups (—C₂H₅).

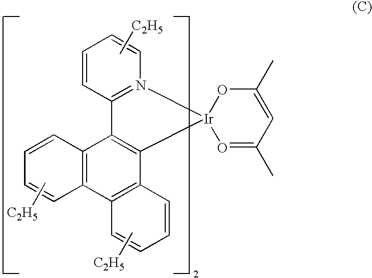

(D) R1, R2, and R3 are propylene groups (—C₃H₇).

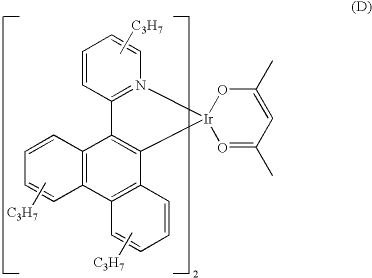

(E) R1, R2, and R3 are phenyl groups (—C₆H₅).

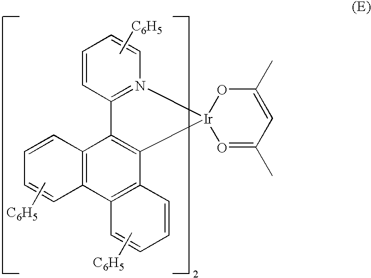

The chemical synthesis steps of this invention are further describe as follows: Synthesis the intermediate compound (Ir(pyp)₂Cl)₂ first. Then mix 3.51 g (Ir(pyp)₂Cl)₂. 5.25 g acetylacetone, and 250 ml dichloromethane in a flask. While stirring the mixture constantly in room temperature, add 9.41 g of 30% sodium methoxide to the mixture, drop by drop. When finished, continue the stirring in room temperature for another 5 hours. Add 250 ml water to extract, remove the organic layer and repeat the extraction process twice. Add MgSO₄ anhydrous into the organic layer and pass it through a filter paper. Collect the filtered compound and place it in a rotary condenser to obtain 3.59 g of the crude Ir(pyp)₂acac. Dissolve the crude Ir(pyp)₂acac in dichloromethane, decolorized it with silica gel and finally obtain the pure Ir(pyp)₂acac by evaporation and purification.

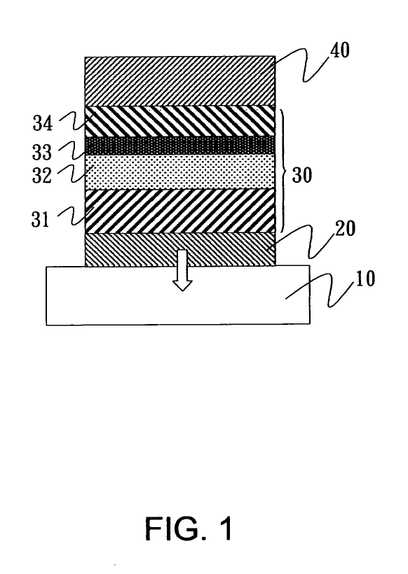

The Ir(pyp)₂acac described in this invention was further applied as a red light guest dopant in the OEL. As shown in FIG. 1, the structure of the OEL in this invention is as follows: a sequentially coat anode (20), an OEL material (30), and a cathode (40) on a flat matrix (10). The OEL material (30) includes a hole transporting layer (31), a light emitting layer (32), a hole blocking layer (33), and an electron transport layer (34). The emitting layer (32) is made of phosphorescent material that contains the aforementioned Ir(pyp)₂acac as a guest emissive dopant. Either a cathode or an anode in the OEL store must be transparent to allow the light transmission. It is better to designate the anode as the transparent side. Metals like indium tin oxide (ITO), gold or platinum are the usually chosen materials for the anode, while Al, Ca, Mg or Mg/Ag alloys are common materials for the cathode.

The detailed procedures in making OEL are as follows: place a cleaned glass substrate, which is plated with a transparent ITO as an anode, onto a holder. Process the thin-layer evaporation and deposit 60 nm N,N′-bis(naphthalene-1-yl)-N,N′-bis(phenyl)benzidine (NPB) sequentially on top of the glass substrate as the hole transport layer, continue the evaporation and deposit of a 30 nm emitting layer of phosphorescent material, which consists of a host compound and a 25% guest dopant where the guest dopant is an iridium complex (Ir(pyp)₂acac) and the host compound is 4,4′-N,N′-bis(N-carbazolyl) biphenyl (CBP); Add 10 nm 2,9-dimethyl-4,7-diphenyl-1,10-phenanthrone (BCP) as the hole blocking layer, and 30 nm 3-(8-hydroxyquinolate) aluminum (Alq3) as the electron transporting layer. Deposit 155 nm Mg/Ag alloy as the cathode.

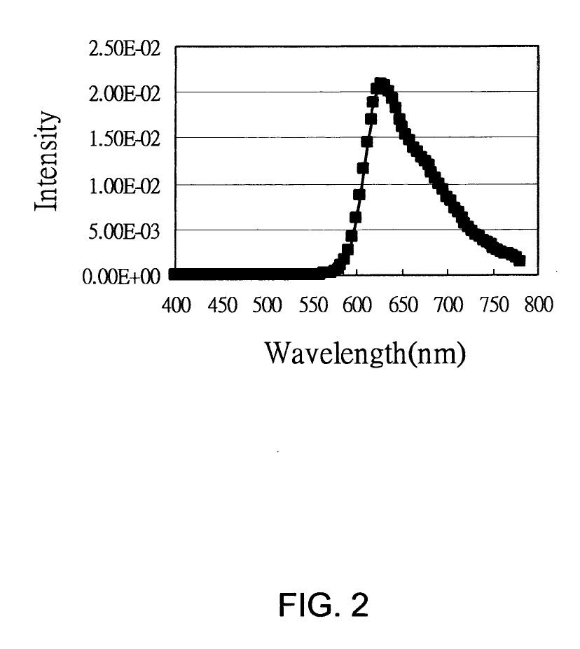

FIG. 2 shows the light emission test results and the wave lengths of the OEL in this invention. The Y-axis indicates the intensity of the light emitted, and the X-axis shows the wavelength. The most intensive light emitted is a near-red light with a 628 mm wavelength. Comparing with its predecessors, this invention has achieved a wave length (x=0.68, y=0.32) which is closer to the standard chromaticity coordinates of red light, as defined by the Commission Internationale de l'Eclairage, and a better thermal stability.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An iridium complex with a chemical formula (I) as follows: 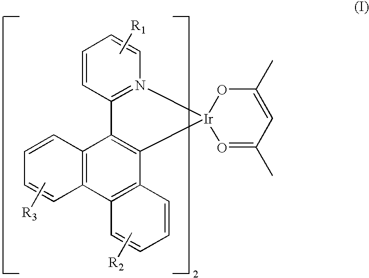
where R1, R2, and R3 are hydrogen atoms, alkyl group with 1 to 3 carbons or aryl group with 6 to 10 carbons.

2. The iridium complex of claim 1, wherein R1, R2, and R3 are hydrogen atoms.

3. The iridium complex of claim 1, wherein R1, R2, and R3 are methyl groups (—CH₃).

4. The iridium complex of claim 1, wherein R1, R2, and R3 are ethyl groups (—C₂H₅).

5. The iridium complex of claim 1, wherein R1, R2, and R3 are propylene groups (—C₃H₇).

6. An iridium complex of claim 1, wherein R1, R2, and R3 are phenyl groups (—C₆H₅).

7. A phosphorescent material made of iridium complex that contains a host compound and a guest dopant which is an iridium complex with the chemical formula (I) as follows: 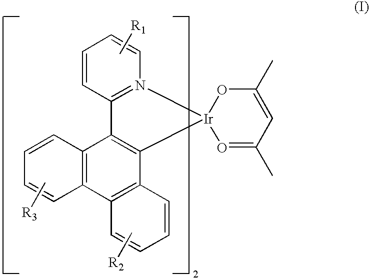
wherein R1, R2, and R3 are hydrogen atoms, alkyl group with 1 to 3 carbons or aryl group with 6 to 10 carbons.

8. The phosphorescent material made of iridium complex of claim 7, wherein R1, R2, and R3 are hydrogen atoms.

9. The phosphorescent material made of iridium complex of claim 7, wherein R1, R2, and R3 are methyl groups (—CH₃).

10. The phosphorescent material made of iridium complex of claim 7, wherein R1, R2, and R3 are ethyl groups (—C₂H₅).

11. A phosphorescent material made of iridium complex of claim 7, wherein R1, R2, and R3 are propylene groups (—C₃H₇).

12. A phosphorescent material made of iridium complex of claim 7, wherein R1, R2, and R3 are phenyl groups (—C₆H₇).

13. An organic electroluminescence (OEL) made of iridium complex, comprising:
a layer of organic light-emitting material composed of a phosphorescent material that includes a host compound and a guest dopant where the iridium complex is the guest dopant with the following chemical formula (I): 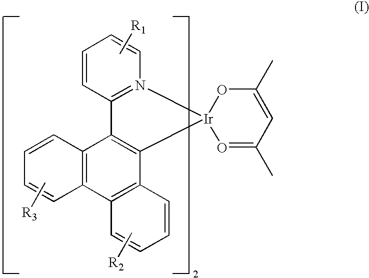
where R1, R2, and R3 are hydrogen atoms, alkyl group with 1 to 3 carbons or aryl group with 6 to 10 carbons; and
a pair of electrode at both sides of the organic light emitting layer for the excitation of the layer of organic light-emitting material.

14. The OEL made of iridium complex of claim 13, wherein R1, R2, and R3 are hydrogen atom.

15. The OEL made of iridium complex of claim 13, wherein R1, R2, and R3 are methyl groups (—CH₃).

16. The OEL made of iridium complex of claim 13, wherein R1, R2, and R3 are ethyl groups (—C₂H₅).

17. The OEL made of iridium complex of claim 13, wherein R1, R2, and R3 are propylene groups (—C₃H₇).

18. The OEL made of iridium complex of claim 13, wherein R1, R2, and R3 are phenyl groups (—C₆H₅).

19. The OEL made of iridium complex of claim 13, wherein the organic lighting material consists of an electron hole porting layer, a light-emitting layer, an electron hole blocking layer and an electron transporting layer.
